(19) United States
(12) Patent Application Publication
(10) Pub. No.: US 2015/0048980 A1
(43) Pub. Date: Feb. 19, 2015

(54) MILLIMETER WAVE TEST FIXTURE FOR AN INTEGRATED CIRCUIT DEVICE UNDER TEST

(71) Applicant: URTN inc., New Taipei City (TW)

(72) Inventor: Yueh-Jung CHIN, New Taipei City (TW)

(73) Assignee: URTN inc., New Taipei City (TW)

(21) Appl. No.: 14/072,357

(22) Filed: Nov. 5, 2013

(30) Foreign Application Priority Data
Aug. 15, 2013 (TW) 102129304

(51) Int. Cl. G01R 29/10

(52) U.S. Cl. CPC G01R 29/105
USPC 343/703

(57) ABSTRACT

A test fixture for an integrated circuit (IC) device under test (DUT) includes: a metallic casing; and first and second antennas secured respectively in first and second RF anechoic chambers in the metallic casing and coupled to a programmable attenuator. The IC DUT is positioned on or in the metallic casing so that an integrated millimeter wave (MMW) antenna thereof is aligned with the first antenna to radiate an MMW signal toward the first antenna through the first RF anechoic chamber. A predetermined MMW signal, which is radiated from an MMW source secured in the second RF anechoic chamber toward the second antenna, is received by the second antenna, is attenuated by the attenuator, and is radiated by the first antenna toward the MMW antenna of the IC DUT.

### CROSS-REFERENCE TO RELATED APPLICATION

This application claims priority of Taiwanese Application No. 102129304, filed on Aug. 15, 2013.

### BACKGROUND OF THE INVENTION

1. Field of the Invention

The invention relates to a test fixture, and more particularly to a millimeter wave (MMW) test fixture for an integrated circuit (IC) device under test (DUT).

2. Description of the Related Art

A conventional radio frequency test system using cables for electrical conduction cannot be used for MMW testing of an IC DUT, which includes, for example, an array of antennas built therein. Therefore, there is proposed an MMW test equipment for such IC DUT. The conventional MMW test equipment adopts the most common test setup, and includes: a radio frequency (RF) anechoic test room; a test antenna disposed in the RF anechoic test room for radiating an MMW signal from a signal source, e.g., a 60 GHz signal; and an electromagnetic wave absorption material, such as one or more stacks of paper sheets chosen for cost considerations, disposed in the RF anechoic test room and serving as an attenuator for attenuating a power level of the MMW signal radiated by the test antenna.

In such a configuration, the RF anechoic test room occupies a relatively large space. In addition, prior to testing, the IC DUT disposed in the RF anechoic test room must be manually aligned with the test antenna and the attenuator, thereby resulting in inconvenience during use. Moreover, accurate attenuation of the MMW signal may not be achieved by such attenuator used in the conventional MMW test equipment.

### SUMMARY OF THE INVENTION

Therefore, an object of the present invention is to provide a millimeter wave (MMW) test fixture for an integrated circuit (IC) device under test (DUT) that can overcome the aforesaid drawbacks of the prior art.

According to the present invention, there is provided a test fixture for an IC DUT. The IC DUT includes an integrated MMW antenna. The test fixture of this invention comprises a metallic casing, a first antenna, an output port, an MMW source, a second antenna and a programmable attenuator.

The metallic casing is configured with first and second radio frequency (RF) anechoic chambers, and a positioning structure adapted for positioning the IC DUT on or in the metallic casing so that the MMW antenna of the IC DUT is capable of radiating an MMW signal into the first RF anechoic chamber.

The first antenna is secured in the first RF anechoic chamber in the metallic casing. The first antenna is opposite to and aligned with the MMW antenna of the IC DUT when the IC DUT is positioned on or in the metallic casing.

The output port is provided on the metallic casing and is coupled to the first antenna.

The MMW source is secured in the second RF anechoic chamber in the metallic casing for generating and radiating a predetermined MMW signal that has desired MMW characteristics.

The second antenna is secured in the second RF anechoic chamber in the metallic casing. The second antenna is opposite to and aligned with the MMW source for receiving the predetermined MMW signal transmitted from the MMW source through the second RF anechoic chamber.

The programmable attenuator is coupled to the first and second antennas. The programmable attenuator is operable to programmably attenuate power of the predetermined MMW signal received by the second antenna based on a control signal.

When the IC DUT serves as a transmitter, the MMW signal radiated by the MMW antenna of the IC DUT is sequentially transmitted through the first RF anechoic chamber, received by the first antenna, and transmitted to the output port. The MMW signal received at the output port is used for evaluation of transmission characteristics of the IC DUT.

When the IC DUT serves as a receiver, the predetermined MMW signal radiated from the MMW source into the second RF anechoic chamber is sequentially received by the second antenna, attenuated by the programmable attenuator, transmitted to the first antenna, radiated by the first antenna to the IC DUT through the first RF anechoic chamber in the metallic casing, and received by the MMW antenna of the IC DUT. The predetermined MMW signal received by the MMW antenna of the IC DUT is used as an input signal for evaluation of reception characteristics of the IC DUT.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view showing the first preferred embodiment of a test fixture for an integrated circuit (IC) device under test (DUT) according to the present invention;

FIG. 2 is a schematic block diagram illustrating the first preferred embodiment of the test fixture;

FIG. 3 is a partially schematic, sectional view showing the first preferred embodiment of the test fixture; and

FIG. 4 is a partially schematic sectional view showing the second preferred embodiment of a test fixture for an IC DUT according to the present invention.

### DETAILED DESCRIPTION OF THE PREFERRED EMBODIMENTS

Before the present invention is described in greater detail, it should be noted that like elements, are denoted by the same reference numerals throughout the disclosure.

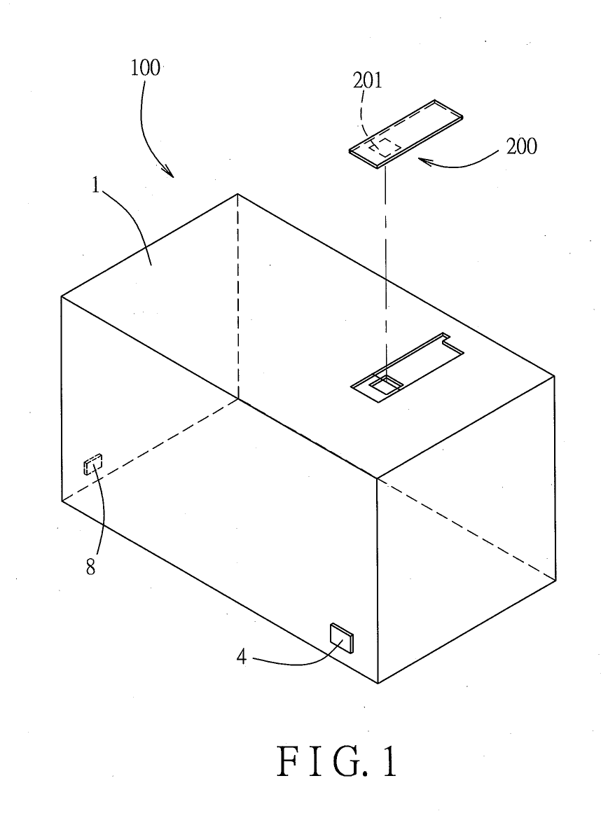

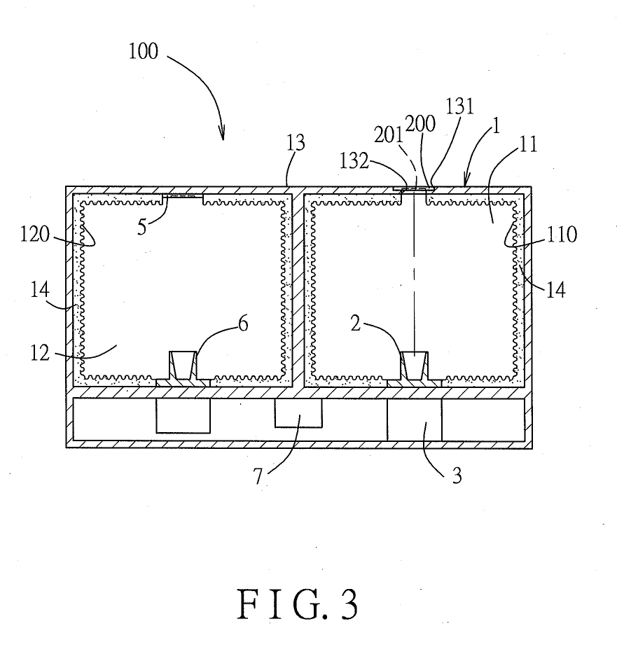

Referring to FIGS. 1 to 3, the first preferred embodiment of a test fixture 100 for an integrated circuit (IC) device under test (DUT) 200 according to the present invention is used to test transmission and reception characteristics of the IC DUT 200. In this embodiment, the IC DUT 200, such as a signal transceiving module, has an integrated millimeter wave (MMW) antenna 201. The test fixture 100 includes a metallic casing 1, a first antenna 2, a three-way connector 3, an output port 4, an MMW source 5, a second antenna 6, a programmable attenuator 7 and a control input port 8.

The metallic casing 1 is configured with rectangular first and second radio frequency (RF) anechoic chambers 11, 12, which are arranged in a horizontal direction in this embodiment. Each of the first and second RF anechoic chambers 11, 12 is defined respectively by an interior wall surface 110, 120 that is covered with radiation absorbing material 14. In this embodiment, the metallic casing 1 has an outer surface 13 that is formed with an engaging groove 131 adapted for releasable engagement with the IC DUT 200, and an opening 132 that is disposed between and communicates with the first RF anechoic chamber 11 and the engaging groove 131 such that the MMW antenna 201 of the IC DUT 200 is exposed through the opening 132 when the engaging groove 131 is engaged with the IC DUT 200, and such that the MMW antenna 201 of the IC DUT 200 is capable of radiating an MMW signal into the first RF anechoic chamber 11 in the metallic casing 1. Therefore, the engaging groove 131 and the opening 132 cooperatively constitute a positioning structure adapted for positioning the IC DUT 200 on the metallic casing 1 so that the MMW antenna 201 of the IC DUT 200 is capable of radiating an MMW signal, e.g., a 60 GHz signal, into the first RF anechoic chamber 11 through the opening 132.

The first antenna 2, such as a horn antenna, is secured in the first RF anechoic chamber 11 in the metallic casing 1, and is aligned with the opening 132 such that the first antenna 2 faces and is aligned with the MMW antenna 201 of the IC DUT 200 when the IC DUT 200 is positioned on the metallic casing 1.

The MMW source 5 is secured in the second RF anechoic chamber 12 in the metallic casing 1 for generating and radiating a predetermined MMW signal, e.g., a 60 GHz signal, which has desired MMW characteristics. In this embodiment, the MMW source 5 is, but not limited to, a reference IC module, i.e., a so-called golden sample of an IC module, that has an integrated MMW antenna (not shown) for radiating the predetermined MMW signal.

The second antenna 6, such as a horn antenna, is secured in the second RF anechoic chamber 12 in the metallic casing 1, and faces and is aligned with the MMW source 5, i.e., the MMW antenna of the reference IC module, for receiving the predetermined MMW signal transmitted from the MMW source 5 through the second RF anechoic chamber 12 in the metallic casing 1.

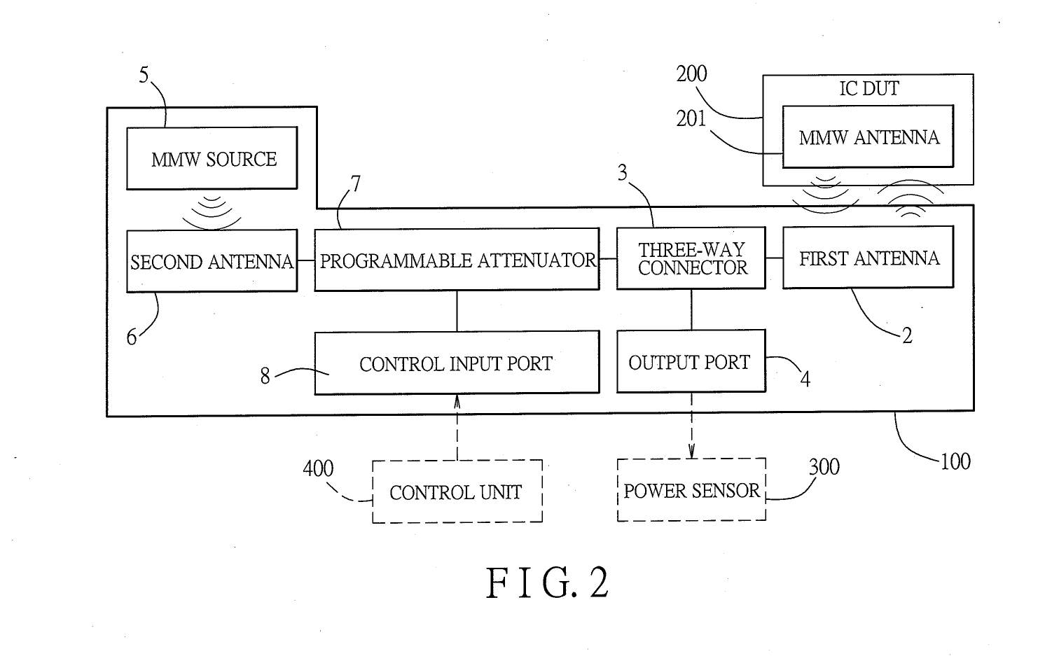

The programmable attenuator 7, such as a voltage controlled attenuator, is coupled to the second antenna 6. The programmable attenuator 7 is operable to programmably attenuate power of the predetermined MMW signal received by the second antenna 6 based on a control signal from a control unit 400 (see FIG. 2).

The control input port 8 is provided on the metallic casing 1, is connected electrically to the programmable attenuator 7, and is adapted to be connected electrically to the control unit 400 for receiving the control signal therefrom. Thus, the control signal from the control unit 400 is transmitted by the control input port 8 to the programmable attenuator 7. In this embodiment, the control input port 8 is a universal serial bus (USB) input port.

The output port 4 is provided on the metallic casing 1, and is adapted to be connected electrically to a power sensor 300 (see FIG. 2).

The three-way connector 3 has three ports coupled respectively to the programmable attenuator 7, the first antenna 2 and the output port 4. It should be noted herein that the three-way connector 3 may be substituted by other multi-way connectors, such as a four-way connector, when it is desired in practice.

When the test fixture 100 is used to test transmission characteristics of the IC DUT 200, i.e., when the IC DUT 200 serves as a transmitter, the MMW signal radiated by the MMW antenna 201 of the IC DUT 200 is sequentially transmitted through the first RF anechoic chamber 11 in the metallic casing 1 to the first antenna 2, received by the first antenna 2, and transmitted to the output port 4 through the three-way connector 3. The MMW signal received at the output port 4 is then outputted to the power sensor 300 for evaluation of the transmission characteristics of the IC DUT 200, e.g., power measurement. Alternatively, the output port 4 can be connected electrically to a spectrum analyzer (not shown) for further measurements related to the MMW signal.

When the test fixture 100 is used to test reception characteristics of the IC DUT 200, i.e., when the IC DUT 200 serves as a receiver, the predetermined MMW signal, which is sequentially radiated from the MMW source 5 into the second RF anechoic chamber 12, received by the second antenna 6, attenuated by the programmable attenuator 7 and transmitted to the first antenna 2 through the three-way connector 3, is radiated by the first antenna 2 to the IC DUT 200 through the first RF anechoic chamber 11 in the metallic casing 1 and received by said MMW antenna 201 of the IC DUP 200. The predetermined MMW signal received by the MMW antenna 201 of the IC DUT 200 is used as an output signal for evaluation of the reception characteristics of the IC DUT, e.g., receiving sensitivity. In this case, when a bit error rate (BER) measuring instrument (not shown) is connected electrically to the IC DUT 200 for measuring BER values of the output signal from the IC DUT 200, the receiving sensitivity of the IC DUT 200 can be obtained based on the BER values measured by the BER measuring instrument.

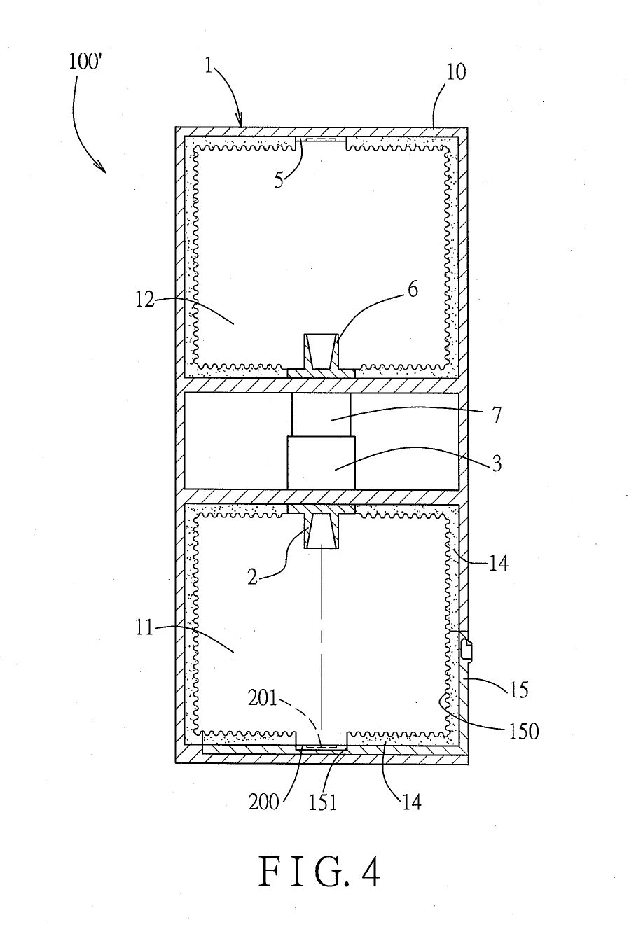

FIG. 4 illustrates the second preferred embodiment of a test fixture 100′ for an IC DUT 200 according to this invention, which is a modification of the first preferred embodiment. Unlike the previous embodiment, the metallic casing 1 includes a main case body 10 and a carrier body 15. The main case 10 is configured with the first and second RF anechoic chambers 11, 12. However, in this case, the first RF anechoic chamber 11 has an open end. The carrier body 15 is movably engaged to the main case body 10 at the open end, and is formed with an engaging groove 151 adapted for releasable engagement with the IC DUT 200. The carrier body 15 is movable relative to the main case body 10 between an open position, where the carrier body 15 moves away from the main case body 10, and a closed position, where the carrier body 15 covers and seals the open end of the first RF anechoic chamber 11 and is disposed in a manner that the MMW antenna 201 of the IC DUT 200, which is engaged to the engaging groove 151 in the carrier body 15, faces and is aligned with the first antenna 2. In other words, the first RF anechoic chamber 11 is essentially defined cooperatively by the main case body 10 and the carrier body 15. Therefore, the engaging groove 151 in the carrier body 15 serves as the positioning structure for positioning the IC DUT 200 on the test fixture 100′ when the carrier body 15 is in the closed position. In addition, the carrier body 15 has an interior surface 150 that is also covered with the radiation absorbing material 14. It is noted that, in this embodiment, the first and second RF anechoic chambers 11, 12 are arranged in a vertical direction.

In view of the above, the test fixture 100, 100′ of this invention integrated with the MMW source 5 and the programmable attenuator 7 can be designed to have a compact size of about 35 cm×18 cm×21 cm to facilitate carrying thereof. In addition, the first and second antennas 2, 6 are arranged to be respectively aligned with the MMW antenna 201 of the IC DUT 200 and the MMW source 5 without manual alignment as required with the prior art, thereby resulting in convenience during use. Moreover, the programmable attenuator 7 can accurately attenuate the predetermined MMW signal received by the second antenna 6 in accordance with the control signal.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A test fixture for an integrated circuit (IC) device under test (DUT), the IC DUT having an integrated millimeter wave (MMW) antenna, said test fixture comprising:
a metallic casing configured with first and second radio frequency (RF) anechoic chambers, and a positioning structure adapted for positioning the IC DUT on or in said metallic casing so that the MMW antenna of the IC DUT is capable of radiating an MMW signal into said first RF anechoic chamber;
a first antenna secured in said first RF anechoic chamber in said metallic casing so that said first antenna is adapted to face and be aligned with the MMW antenna of the IC DUT when the IC DUT is positioned on or in said metallic casing;
an output port provided on said metallic casing and coupled to said first antenna;
an MMW source secured in said second RF anechoic chamber in said metallic casing for generating and radiating a predetermined MMW signal that has desired MMW characteristics;
a second antenna secured in said second RF anechoic chamber in said metallic casing, and facing and being aligned with said MMW source for receiving the predetermined MMW signal transmitted from said MMW source through said second RF anechoic chamber in said metallic casing; and
a programmable attenuator coupled to said first and second antennas, said programmable attenuator being operable to programmably attenuate power of the predetermined MMW signal received by said second antenna based on a control signal;
wherein, when the IC DUT serves as a transmitter, the MMW signal radiated by the MMW antenna of the IC DUT into said first RF anechoic chamber is sequentially received by said first antenna and transmitted to said output port, the MMW signal received at said output port being used for evaluation of transmission characteristics of the IC DUT; and
wherein, when the IC DUT serves as a receiver, the predetermined MMW signal radiated from said MMW source into said second RF anechoic chamber is sequentially received by said second antenna, attenuated by said programmable attenuator, transmitted to said first antenna, radiated by said first antenna to the IC DUT through said first RF anechoic chamber in said metallic casing, and received by the MMW antenna of the IC DUT, the predetermined MMW signal received by the MMW antenna of the IC DUT being used for evaluation of reception characteristics of the IC DUT.

2. The test fixture as claimed in claim 1, wherein each of said first and second RF anechoic chambers is defined by an interior wall surface that is covered with radiation absorbing material.

3. The test fixture as claimed in claim 1, further comprising a control input port provided on said metallic casing, connected electrically to said programmable attenuator, and adapted for receiving the control signal and transmitting the control signal to said programmable attenuator.

4. The test fixture as claimed in claim 3, wherein-said control input port is a universal serial bus (USB) input port.

5. The test fixture as claimed in claim 1, wherein said programmable attenuator is a voltage controlled attenuator.

6. The test fixture as claimed in claim 1, wherein said metallic casing has an outer surface that is formed with an engaging groove adapted for releasable engagement with the IC DUT, and an opening that is disposed between and communicates with said first RF anechoic chamber and said engaging groove for exposing the MMW antenna of the IC DUT to said first RF anechoic chamber when said engaging groove is engaged with the IC DUT, and that is aligned with said first antenna such that the MMW antenna of the IC DUT faces and is aligned with said first antenna when said engaging groove is engaged with the IC DUT, said engaging groove and said opening constituting said positioning structure.

7. The test fixture as claimed in claim 1, wherein said metallic casing includes a main case body configured with said first and second RF anechoic chambers, and a carrier body movably engaged to said main case body and formed with an engaging groove adapted for releasable engagement with the IC DUT, said first RF anechoic chamber having an open end, said carrier body being movable relative to said main case body between an open position, where said carrier body moves away from said main case body, and a closed position, where said carrier body covers and seals said open end of said first RF anechoic chamber, and is disposed in a manner that the MMW antenna of the IC DUT faces and is aligned with said first antenna when the IC DUT is engaged to said engaging groove in said carrier body, said engaging groove in said carrier body serving as said positioning structure when said carrier body is in the closed position.

8. The test fixture as claimed in claim 1, further comprising a three-way connector that has three ports coupled respectively to said programmable attenuator, said first antenna and said output port.

9. The test fixture as claimed in claim 1, wherein said MMW source is a reference IC module that has an integrated MMW antenna for radiating the predetermined MMW signal.

10. The test fixture as claimed in claim 1, wherein each of said first and second antennas is a horn antenna.
